(19) United States
(12) Patent Application Publication
(10) Pub. No.: US 2026/0348048 A1
(43) Pub. Date: Nov. 5, 2026

(54) METHOD OF MANUFACTURING SINGLE CRYSTAL DIAMONDS

(71) Applicant: Element Six Technologies Limited, Oxfordshire (GB)

(72) Inventors: William Joseph HILLMAN, Oxfordshire (GB); Stephanie LIGGINS, Oxfordshire (GB); Benjamin WICKHAM, Oxfordshire (GB); Benjamin Simon TRUSCOTT, Oxfordshire (GB)

(21) Appl. No.: 19/476,579

(22) PCT Filed: Apr. 23, 2024
(86) PCT No.: PCT/EP2024/061073

§ 371 Date: Oct. 17, 2025

(30) Foreign Application Priority Data
Apr. 24, 2023 (GB) 2305972.8

(51) Int. Cl. C30B 25/20; C30B 25/18; C30B 28/14; C30B 29/04

(52) U.S. Cl. CPC C30B 25/20; C30B 25/186; C30B 28/14; C30B 29/04

(57) ABSTRACT

A method of manufacturing a plurality of single crystal diamonds. A first and a second single crystal diamond substrate are located on a carrier. Each single crystal diamond substrate comprises a growth surface lying within 15° of a {100} crystallographic plane and edges lying within 15° of a {100} crystallographic plane. The first single crystal diamond substrate is separated from the second single crystal diamond substrate with a centre-to-centre separation perpendicular to a {110} plane relative to a longest edge length of the single crystal diamond substrate of at least √2 and no more than 2. The carrier and the single crystal diamond substrates are placed into a chemical vapour deposition reactor and a first single crystal diamond and a second single crystal diamond are grown on the first and a second single crystal diamond substrates respectively.

### FIELD OF THE INVENTION

This disclosure relates chemical vapour deposition (CVD) single crystal diamond, and methods of manufacturing CVD single crystal diamond.

### BACKGROUND

Interest in the chemical vapour deposition (CVD) synthesis of diamond began in the 1980s, and research by various groups around the world continues to the present day. Most of the published work on single crystal CVD diamond material has disclosed growth of thin (<1 mm) layers via homoepitaxial growth on single crystal diamond substrates, predominantly using microwave plasma CVD. Successful synthesis of thick, high quality single crystal CVD diamond material depends on the stable maintenance of physically extreme process conditions over periods of many days, typically requiring highly specialized synthesis hardware.

Diamond has high thermal conductivity, wide transparency, low dielectric loss, hardness, and other well-known properties. These characteristics, alone or in combination, make it valuable in numerous scientific and technical applications. Synthetic diamond material can be engineered to possess advantageous properties, and examples of applications for which it is uniquely suited are known in the art. Advancing technology has improved the availability of synthetic diamond, which can now be found in consumer applications as well as increasingly many technical ones such as mechanical wear elements and optical elements.

One such application that has gained prominence in recent years is the use of synthetic diamond gems in jewellery. For polished goods of a given quality, the market price is largely determined by the size (mass) of the gem, and the maximum mass obtainable in a given shape is in turn determined by the minimum linear dimension of the parent crystal, which for CVD crystals is commonly the thickness (as opposed to the width or depth). For example, the round brilliant (RB) gem shape typically requires a minimum dimension of around 4 mm to produce a 1 carat (1 ct) part, while about 5.5 mm is required for a 2 ct RB, both assuming no constraint in the other dimensions. One aspect that is used to distinguish diamond gems of higher versus lower quality is their colour, to the extent that diamonds are sometimes assigned a colour “grade” prior to being marketed to consumers. Such a grade is related to the magnitude of optical absorption exhibited by a given gem. The industry-standard Gemological Institute of America (GIA) colour grades D, E, and F constitute the “colourless” category, while grades and G, H, I, and J are considered “near-colourless”.

For certain optical applications, it is desirable to provide a material which has low optical absorbance, and which may be assigned a “colourless” grade of D, E, or F when polished as a gem. Such a material can constitute a single crystal CVD synthetic diamond material which has a low concentration of impurities, which would otherwise increase the optical absorbance of the material. It is also the case that material suitable for colourless gems may possess properties that are desirable as well for certain optical applications. WO20041046427 and WO2007/066215 describes CVD single crystal diamond for use in optical applications.

It is desirable to produce CVD synthetic single crystal diamond material as economically as possible, whether this is for gem or industrial applications. An important factor is the number of single crystal diamonds able to be grown simultaneously in a single reactor, and the growth rate achievable when doing so.

Faster growth of fewer single crystals at once can produce diamond at an equivalent volumetric rate to slower growth of more single crystals in a given run. However, higher growth rates can have an adverse effect on material quality and overall yield, as the process is more difficult to control, and cracking of the single crystal diamond can occur during or after growth. It is therefore well known to synthesize a plurality of single crystal CVD diamonds together within a reactor.

Typically, a plurality of single crystal CVD synthetic diamonds is fabricated in a single CVD growth run by providing a plurality of single crystal diamond substrates on a carrier, for example as described in WO2017/050620. The carrier is typically formed of a carbide forming material such as silicon, silicon carbide, or refractory metals such as molybdenum, tungsten, titanium, etc. A plurality of single crystal diamond substrates can be located on the refractory metal carrier or bonded thereto by soldering or brazing.

One way to maximise the yield in a particular reactor for a given growth run is to use multiple substrates together in a tiled configuration. Tiling is typically used to create large area single crystal diamond, for example as described in Yamada et al., Diamond & Related Materials 33 (2013) 27-31. However, tiling is difficult in practice as dislocations and other discontinuities can arise from the interface between adjacent substrate tiles and these give rise to a large area grown single crystal with a network of dislocations that can lead to cracking or optical imperfections.

### SUMMARY OF THE INVENTION

It is an object to provide a method that improves the yield of single crystal diamond during a single run of CVD synthesis while retaining adequate quality and control of properties of the grown single crystal diamond.

According to a first aspect, there is provided a method of manufacturing a plurality of single crystal diamonds. The method comprises locating a first and a second single crystal diamond substrate on a carrier. Each single crystal diamond substrate comprises a growth surface lying within 15° of a {100} crystallographic plane and edges lying within 15° of a {100} crystallographic plane. The first single crystal diamond substrate is separated from the second single crystal diamond substrate with a centre-to-centre separation perpendicular to a {110} plane relative to a longest edge length of the single crystal diamond substrate of at least 2 and no more than 2. The carrier and the single crystal diamond substrates are placed into a chemical vapour deposition reactor and a first single crystal diamond and a second single crystal diamond are grown on the first and a second single crystal diamond substrates respectively.

As an option. the method comprises locating more than two single crystal diamond substrates on the carrier.

Optionally, the first single crystal diamond substrate is separated from the second single crystal diamond substrate with a centre-to-centre separation perpendicular to a {110} plane relative to a longest edge length of the single crystal diamond substrate selected from any of no more than 1.9, no more than 1.8, no more than 1.7, no more than 1.6 and no more than 1.5.

As an option, each single crystal diamond substrate has a largest lateral dimension selected from any of at least 2 mm, at least 3 mm, at least 4 mm and at least 5 mm, at least mm, at least 10 mm.

As an option, each single crystal diamond has a height above the single crystal diamond substrate growth surface selected from any of at least 0.5 mm, at least 1 mm, at least 2 mm, and at least 3 mm, at least 5 mm, at least 7 mm, and at least 10 mm.

As an option, a sum of an area in plan view of the diamond substrates defines a total diamond substrate area, a sum of an area in plan view of the grown single crystal diamonds defines a total grown diamond area, and the total diamond substrate area is between 45% and 60% of the total grown diamond area.

As an option, the first and second diamond substrates are substantially rectangular in plan view, and have an aspect ratio between 1.5 and 3.

The carrier optionally has a largest dimension in a range 30 mm to 200 mm.

The method optionally further comprises, prior to locating the first and the second single crystal diamond substrate on the carrier, coating the carrier with a layer of polycrystalline CVD diamond material, bonding the first and second single crystal diamond substrates to the layer of polycrystalline CVD diamond material on the carrier.

The layer of polycrystalline CVD diamond formed on the carrier optionally has a thickness in a range 20 μm to 200 μm.

The first and second single crystal diamond substrates are optionally bonded to the layer of polycrystalline CVD diamond material on the carrier via any of brazing and soldering to ensure a good thermal contact.

According to a second aspect, there is provided a diamond product comprising a carrier. A first and a second single crystal diamond substrate are located on the carrier. Each single crystal diamond substrate comprises a growth surface lying within 15° of a {100} crystallographic plane, and edges lying within 15° of a {100} crystallographic plane. The first single crystal diamond substrate is separated from the second single crystal diamond substrate with a centre-to-centre separation perpendicular to a {110} plane relative to a longest edge length of the single crystal diamond substrate of at least √2 and no more than 2.

As an option, the diamond product further comprises more than two single crystal diamond substrates on the carrier.

As an option, the first single crystal diamond substrate is separated from the second single crystal diamond substrate with a centre-to-centre separation perpendicular to a {110} plane relative to a longest edge length of the single crystal diamond substrate selected from any of no more than 1.9, no more than 1.8, no more than 1.7, no more than 1.6 and no more than 1.5.

Each single crystal diamond substrate optionally has a largest lateral dimension selected from any of at least 2 mm, at least 3 mm, at least 4 mm and at least 5 mm, at least mm, at least 10 mm.

As an option, the first and second diamond substrates are substantially rectangular in plan view, and have an aspect ratio between 1.5 and 3.

The carrier optionally has a largest dimension in a range 30 mm to 200 mm.

As an option, the carrier is coated with a layer of polycrystalline CVD diamond material, and the first and second single crystal diamond substrates are bonded to the layer of polycrystalline CVD diamond material on the carrier.

The layer of polycrystalline CVD diamond formed on the carrier optionally has a thickness in a range 20 μm to 200 μm.

The first and second single crystal diamond substrates are optionally bonded to the layer of polycrystalline CVD diamond material on the carrier via any of brazing and soldering to ensure a good thermal contact.

According to a third aspect, there is provided a single crystal diamond manufactured using the method as described above in the first aspect.

### BRIEF DESCRIPTION OF THE DRAWINGS

The invention will now be more particularly described, by way of example only, with reference to the accompanying drawings, in which:

FIG. 1 illustrates schematically a cross-section view of a single crystal diamond grown on a {100} substrate;

FIG. 2 illustrates schematically in plan view a carrier with a plurality of single crystal diamond substrates in an array according to an embodiment;

FIG. 3 illustrates schematically in plan view a carrier with a plurality of grown single crystal diamonds in an array according to an embodiment;

FIG. 4 illustrates schematically in plan view the corner-to-corner spacing of adjacent single crystal diamond substrates;

FIG. 5 shows an array of grown single crystal CVD diamonds on a carrier according to an embodiment;

FIG. 6 shows in plan view a grown single crystal CVD diamond according to an embodiment;

FIG. 7 is a flow diagram showing exemplary steps to manufacture a plurality of single crystal diamonds;

FIG. 8 illustrates schematically in plan view a loading pattern with high aspect ratio single crystal diamond substrates according to an embodiment; and

FIG. 9 illustrates schematically in plan view a loading pattern with high aspect ratio single crystal diamond substrates according to an alternative embodiment.

The figures are not drawn to scale. Throughout the description, similar parts have been assigned the same reference numerals, and a detailed description is omitted for brevity.

### DETAILED DESCRIPTION

In known CVD synthetic diamond processes, the growth face of the base substrate may be in a variety of crystallographic orientations. The most usual orientation that is used for growth of high quality CVD diamond material is generally a plane defined by the Miller indices (001). Throughout this specification, the Miller indices {hkl}, defining a plane based on the axes x, y and z will be written assuming that the z direction is that normal or within 5° or within 3° of the normal to the growth face of the base substrate and parallel to the growth direction. The axes x and y are then within the plane of the growth face of the base substrate, and are generally equivalent by symmetry.

During homoepitaxial single crystal growth, the material formed by growth on any particular crystallographically oriented surface is generally referred to as the “growth sector” for that surface. For example, material formed by growth on an (001) surface is referred to as the (001) growth sector.

During a CVD diamond material process there is homoepitaxial single crystal growth from the major growth surface (typically the (001) surface). This growth occurs not only normal to the growth surface of the base substrate but may also extend laterally therefrom. Therefore, as the growth process takes place, there is both thickening of the CVD grown diamond layer and also lateral extension of the grown diamond layer relative to the base diamond substrate. The lateral growth may be the same growth sector as the major growth surface (in the usual case the (001) growth sector), which is then enlarged in lateral area relative to that of the growth surface of the base substrate. Alternatively, the lateral growth may be other growth sectors, such as {113}. Whether or not the lateral growth is the same growth sector or a different growth sector from the major growth surface depends on the growth conditions.

In addition to homoepitaxial single crystal growth from the major growth surface, there is also homoepitaxial single crystal growth from the side surfaces of the base substrate. Thus, for the typical case where the growth surface is a (001) surface, growth occurs not only on the (001) face but also on the side surfaces, which may, in the case of a square or rectangular surface, for example, be {100} surfaces. The growing diamond single crystal is typically continuous across the growth sector boundary between areas of growth formed by different growth facets.

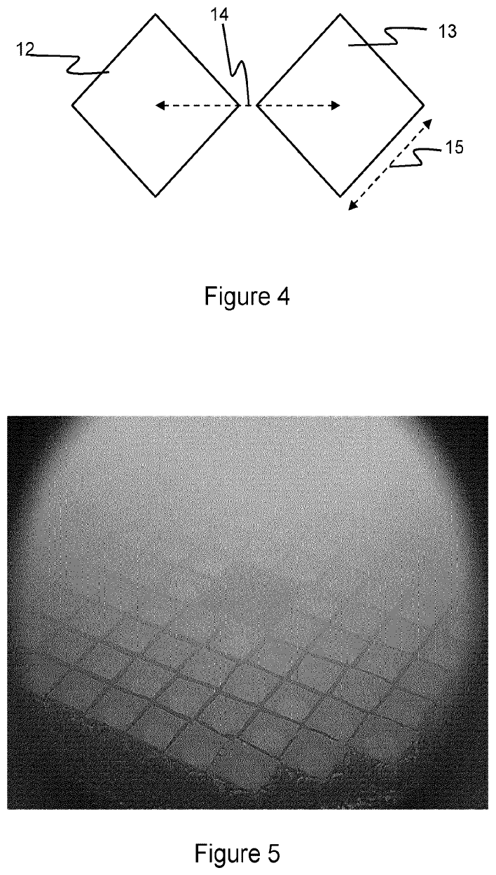

U.S. Pat. No. 6,096,129 describes a method of growing diamond material on a substrate surface such that the grown diamond material has a larger area than the starting substrate. U.S. Pat. No. 6,096,129 describes providing an initial single crystalline diamond base material, onto which single crystalline diamond material is homoepitaxially vapour deposited to provide a resulting diamond material that is cut and polished to provide a successive base material onto which single crystalline material is again grown, thereby forming a single crystalline diamond material having a large area. As exemplified in FIGS. 4A-4C of U.S. Pat. No. 6,096,129, the initial base material is substantially square with {100} side surfaces, growth taking place predominantly on an upper {001} surface, that growth taking place laterally as well as normally from the upper {001} surface so that the grown surface has enlarged lateral dimensions compared to those of the initial base material. The successive base material that is cut from the grown diamond material is square in cross-section. The sides of the square are rotated 45° relative to the sides of the initial base material, and have <110> edges. The area of the square cross section of the successive base material is less than twice the area of the square cross-sectional area of the initial base material, due to the encroachment of {111} faces in the grown diamond material. This successive base material is then used for further growth, this further growth being from the <110> edges. The preferred growth rate ratio α (as defined by the ratio [√3× growth rate in <001>]+[growth rate in <111>]) is said to be at least 3:1. Using the techniques described in U.S. Pat. No. 6,096,129, and by taking advantage of “rotation” during CVD diamond growth on an {001} surface, the surface area of the growth face of the diamond can be significantly greater than the surface area of the growth face of the substrate from which the CVD diamond was grown.

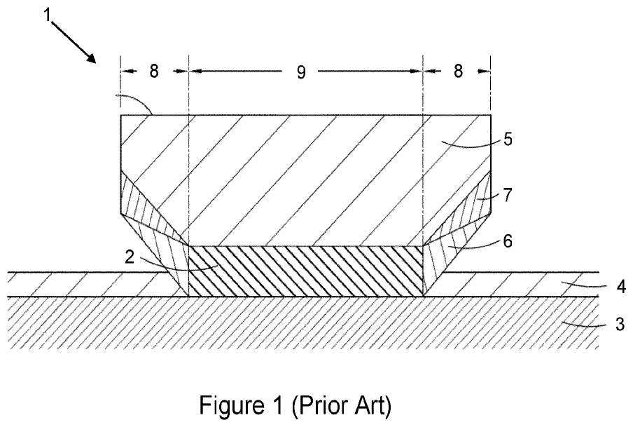

FIG. 1 illustrates a cross-sectional view of such a diamond 1. A single crystal substrate 2 is affixed to a carrier 3. To improve thermal management during the growth process, the single crystal substrate 2 may be affixed to the carrier by brazing as described in U.S. Ser. No. 10/590,563, or in some other way to ensure a good thermal contact between the single crystal diamond substrate 2 and the carrier 3. In practice, a plurality of substrates 2 are affixed to a single carrier 3.

Once the single crystal substrates 2 have been affixed to the carrier 3, the carrier 3 is loaded into a CVD reactor and subjected to a single crystal CVD diamond growth process. A wide range of single crystal CVD diamond materials and associated growth conditions are known in the art including high purity processes, nitrogen doping processes, boron doping processes, co-doping processes, and layered single crystal CVD diamond growth processes. Single crystal diamond grows homoepitaxially on the single crystal substrate 2, and a layer of polycrystalline CVD diamond material 4 grows in the regions between the single crystal substrates 2.

Growth of the single crystal CVD diamond material on the plurality of single crystal diamond substrates 2 is controlled such that a vertical growth of the single crystal CVD diamond material on the single crystal diamond substrates 2 is higher than a vertical growth of polycrystalline CVD diamond material 4 growing on the polycrystalline CVD diamond layer exposed between the single crystal diamond substrates. Inevitably, there will be some degree of polycrystalline CVD diamond growth 24 between the single crystal diamond substrates. However, growth conditions may be selected to ensure that the polycrystalline CVD diamond material does not overgrow the single crystal CVD diamond material or otherwise compete with the single crystal CVD diamond growth. For example, according to certain examples the polycrystalline CVD diamond layer is grown at a temperature over 1000 °C and the single crystal CVD diamonds are grown at a temperature under 1000 °C. Using different growth regimes for the polycrystalline CVD diamond layer and the single crystal CVD diamonds aids in ensuring that the polycrystalline CVD diamond material does not unduly compete with the single crystal CVD diamond growth.

There is single crystal growth from the (001) growth sector 5, from the (010) growth sector 6 (from the side faces of the substrate 2) and from the (011) growth sector 7 (from the vertices of the substrate 2). Although the different single crystal diamond material growth sectors are hatched differently in FIG. 1 for clarity in the cross-sectional views, in reality they form a continuous crystal.

After growth of the single crystal CVD diamond 1 the growth run is terminated. Advantageously, the structure as shown in FIG. 1 is cooled down at a rate which is sufficient to spontaneously delaminate the polycrystalline CVD diamond layer 4 from the carrier 3 to form a free-standing single crystal diamond.

FIG. 1 also illustrates the differentiation between a lateral growth region 8 and a vertical growth region 9 as defined in the present invention. It is understood that lateral growth is associated with the vertical growth from the major growth surface (by which we mean growth normal to the major growth surface of the substrate 2), i.e. the lateral growth of the “growth sector of the major surface” is associated with the thickening of that growth sector. The CVD single crystal diamond material grown as described herein is defined as having two distinct regions, as follows: the material that extends above the plane of the substrate surface on which growth takes place and outside of the peripheral boundary of the original substrate (as viewed along the direction normal to the major growth face of the substrate) is referred to as the “lateral growth region”; and that which extends above the original substrate (i.e. confined within the peripheral boundary of the original substrate as viewed along the direction normal to the major growth face of the substrate) as the “vertical growth region”. This lateral growth region can be distinguished from any laterally extending growth occurring as a result of carbon depositing directly on the side surfaces of the first diamond substrate during the CVD process, as it lies above (i.e. in the growth direction) the plane defined by the original major growth face.

Because of the rotation during growth, the packing density of (100) single crystal substrates 2 on a carrier 3 has been limited by the geometry and expected rotation. The substrates 2 are spaced apart to allow for rotation of the growing single crystal diamond.

The inventors have realised that there is an advantage in closer packing of the substrates on the carrier where diamond rotation occurs during growth. It has been found that close packing of {100} faced substrates in a corner-to-corner configuration constrains lateral growth and edge development during growth. Furthermore, the restriction of edge-morphology and very close approach of the adjacent growing diamonds appears to form a pseudo-wafer-like structure between adjacent diamonds, with mutual heat sinking between adjacent diamonds. This allows the diamonds to resist edge-twinning to a higher synthesis temperature and over a larger carrier area.

Note that similar close packing can be used for substrates on a carrier where diamond rotation does not occur, for example when using {100} faced substrates or when growing from {110} faced substrates under conditions that restrict rotation.

In addition to the technical advantages of a higher density of substrates 2 on a carrier, there are economic benefits. There is a minimal change to the power density required to grow diamonds when the substrates are packed more closely as described herein, so reductions of over 40% in required power can be achieved to grow the same volume of diamond as could be grown using prior art techniques. Furthermore, it has been found that the yield improves because the grown diamonds have less tendency to twin with no loss of growth rate.

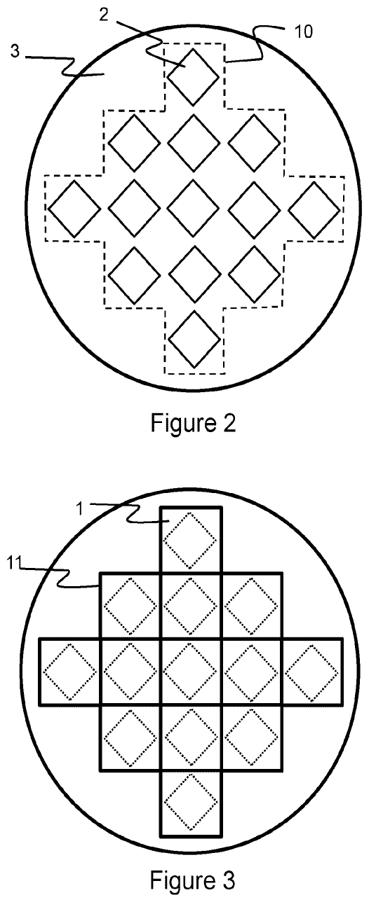

FIG. 2 illustrates schematically in plan view a carrier with a plurality of single crystal diamond substrates in an array according to an embodiment. FIG. 3 illustrates schematically in plan view the same carrier with a plurality of grown single crystal diamonds in an array after homoepitaxial growth of CVD single crystal diamonds on each substrate according to an embodiment.

The substrates 2 are disposed on the carrier 3. This may be by locating in a recess, brazing, or otherwise locating the substrates 2 in place. Each substrate comprises a growth surface lying within 15° of a {100} crystallographic plane.

The carrier is then placed into the CVD reactor and the plurality of single crystal diamonds is grown, one on each diamond substrate of the plurality of substrates. At the end of the growth process, each single crystal diamond 11 of the plurality of single crystal diamonds is separated from an adjacent single crystal diamond of the plurality of single crystal diamonds by a layer of polycrystalline diamond (illustrated schematically by a thick black line). Note that a layer of polycrystalline diamond is found on each opposing face, and these polycrystalline layers may meet or may have a gap between them. Each single crystal diamond of the plurality of single crystal diamonds is separated from an adjacent single crystal diamond by a median distance between adjacent faces in a range of 5 μm to 2.5 mm. In some embodiments, the thickness of the polycrystalline diamond layer is in a range selected from any of 5 μm to 2 mm, 5 μm to 1 mm, and 5 μm to 0.5 mm.

During growth, the diamond substrate 2 presents a (001) major surface, which major surface is bounded by at least one <100> edge, and the method comprises growing diamond material homoepitaxially on the (001) major surface of the diamond material. Growth may be continued in one or more steps until there is a sufficient thickness of grown diamond material that the associated lateral growth of the diamond material is sufficiently great that full effective rotation of the said (001) major surface of the diamond material is achieved.

By full effective rotation of the said (001) major surface of the diamond material being achieved, it is meant that the side of the said (001) major surface bounded in the starting substrate by the at least one <100> edge is bounded in the grown substrate by two orthogonal <110> edges which intersect each other, and which encompass and replace the whole of the edge originally defined by the at least one <100> edge.

In a preferred embodiment of the invention the (001) major surface is bounded in the first substrate solely by four <100> edges, and full effective rotation of the said (001) major surface of the diamond material results in the formation of four <110> edges, in the form of two parallel pairs which are orthogonal to one another, which encompass all four <100> edges of the first substrate. Each <110> edge, when projected on the plane defined by the original substrate major growth face, either touches a respective one of the four points of intersection of the original <100> edges (the corners of the growth face of the substrate) or is displaced laterally outwards from those points of intersection by lateral growth, forming a final grown diamond material which has have a major grown surface that is essentially square.

As used herein, the terms <100> edge and <110> edge include edges that are exactly <100> and <110> edges respectively, which are advantageous, and also edges that are up to 5°, or up to 3°, of the <100> and <110> directions respectively.

Each single crystal diamond substrate 2 has a largest lateral dimension selected from any of at least 2 mm, at least 3 mm, at least 4 mm, at least 5 mm, and at least 10 mm.

Each single crystal diamond 11 has a height above the growth surface selected from any of at least 0.5 mm, at least 1 mm, at least 2 mm, and at least 3 mm, at least 5 mm, at least 7 mm, and at least 10 mm.

The dotted line 10 in FIG. 2 shows the total grown diamond area, and the substrates 2 have a total diamond substrate area. In an embodiment, the total diamond substrate area is between 45% and 60% of the total grown diamond area. Note that this may change if the substrates are not substantially square in plan view.

Owing to rotation during growth, each single crystal diamond of the plurality of single crystal diamonds comprises a plane on an outer surface lying within 15° of a {110} crystallographic plane.

The growth surface of each substrate 2 lies at an angle relative to the {100} crystallographic plane selected from any of within 15°, within 10°, within 7°, within 5° and within 2°.

Turning now to FIG. 4, in this example the diamond substrates 2 are substantially square in plan view. Here, a first substrate 12 and a second substrate 13 are shown, they typically have at least one corner separated from an adjacent diamond substrate corner with an average spacing of between 5 μm and 3 mm. The centre-to-centre separation 14 between the first substrate 12 and the second substrate 13 is between 12 and 2 relative to the longest edge length 14 of a single crystal diamond substrate 12, 13. The centre-to-centre separation is measured substantially perpendicular to a {110} plane of the single crystal diamond substrates 12, 13, bearing in mind that the edges of the single crystal diamond substrates 12, 13 lie within 15° of a {100} plane. The upper limit of the separation may be selected from no more than 1.9, no more than 1.8, no more than 1.7, no more than 1.6 and no more than 1.5.

FIG. 5 shows an array of grown single crystal CVD diamonds on a carrier according to an embodiment. It can be seen that the rotation of the grown diamond has given rise to faces in very close proximity to adjacent grown diamonds, making good use of the available carrier area.

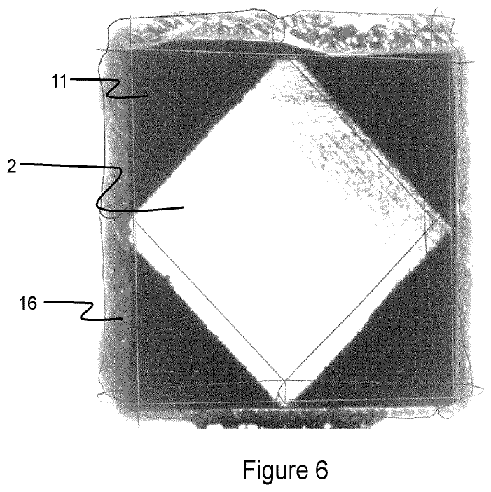

FIG. 6 shows in plan view a grown single crystal CVD diamond according to an embodiment. The grown diamond 11 also shows the substrate 2 and the polycrystalline diamond skin 16F around the edges of the grown diamond 11.

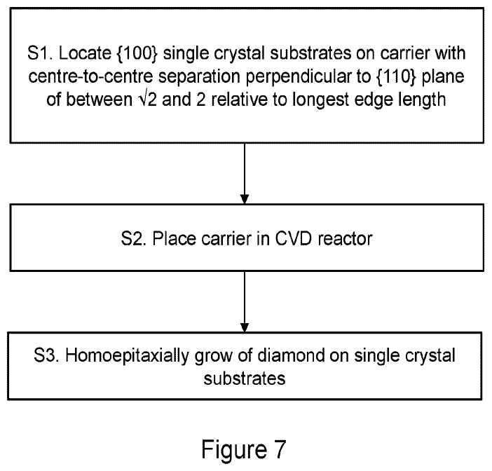

FIG. 7 is a flow diagram illustrating exemplary steps in manufacturing a plurality of single crystal diamonds. The following numbering corresponds to that of FIG. 7:

S1. A first and a second single crystal diamond substrate are located on a carrier, wherein each single crystal diamond substrate comprises a growth surface lying within 15° of a {100} crystallographic plane and edges lying within 15° of a {100} crystallographic plane. The first single crystal diamond substrate is separated from the second single crystal diamond substrate with a centre-to-centre separation perpendicular to a {110} plane relative to a longest edge length of the single crystal diamond substrate of at least √2 and no more than 2. In practice, more than two single crystal diamond substrates would likely be located on the carrier.

In an exemplary embodiment, the carrier is coated with a layer of polycrystalline CVD diamond material prior to locating the single crystal diamond substrates on it, typically with a thickness of between 20 μm to 200 μm. The first and second single crystal diamond substrates are typically bonded to the layer of polycrystalline CVD diamond material using brazing or soldering to ensure a good thermal contact, which allows for improved heat management during the growth process.

S2. The carrier and single crystal diamond substrates is placed into a chemical vapour deposition reactor.

S3. A single crystal diamond is grown homoepitaxially on the first and second single crystal diamond substrates.

As described above, close packing of {100} faced substrates in a corner-to-corner configuration constrains lateral growth and edge development during growth. The close approach of the adjacent growing diamonds appears is thought to provide mutual heat sinking between adjacent diamonds. This is a route to very thick (for example, greater than 5 mm or greater than 10 mm) diamonds. Typically, recessing is used to grow very thick diamonds.

Recessing requires providing a heat sink to the sides of the diamonds during growth, but as the diamond get thicker the diamonds must be removed from one recess and placed in a thicker recess, or the thickness of the recess must otherwise be increased. By using the close packing techniques described herein, there is no requirement to periodically re-set growing diamonds in deeper recesses to achieve thick diamonds.

### EXAMPLE

A plurality of CVD single crystal diamond substrates was fabricated as transversely cut plates, as described in WO2004/027123. The plates had (100)-oriented faces and edges, and were finished with dimensions of 4.5×4.5×0.3 mm where required to make a 1 ct round brilliant gem product, or 5.5×5.5×0.3 mm for a similar 2 ct product. The substrates were attached to a suitably prepared substrate carrier as described above and placed in a CVD reactor.

The design and construction of the CVD reactor was such as to minimize sources of silicon impurity in the diamond material. For example, the fused silica dielectric barrier, which constituted a minor portion of the process-exposed surface area of the reactor as described in WO2012/084660, was well-cooled and situated far from the deposition area. Such a reactor can offer process purity sufficient to produce the electronic-grade single crystal CVD diamond disclosed in WO01/096633 and WO01/096634.

Process gases were fed into the CVD reactor that included molecular hydrogen, a carbon-containing gas (in this example, methane) and a nitrogen-containing gas (here, molecular nitrogen). CVD reactors used by different practitioners vary widely in their performance characteristics, and the synthesis processes employed can also differ in incidental but nonetheless significant ways, for example by growth temperature. Accommodations for these differences are known in the art. The C₂H₂/H₂ ratio was chosen so that the growth rate was in an optimum range having regard to material quality, uniformity, and process inputs such as the total volume of gas and the total quantity of electrical power required during the course of synthesis. The optimum growth rate range was achieved using 2.5 to 3.5% C₂H₂/H₂ equivalent (CH₄/H₂ ratio between 5.5 and 7.5%).

Microwave energy was supplied at a frequency of either 896 or 915 MHz and a plasma of the process gases was formed within the reactor. The required operating frequency largely depends on the dimensions of the reactor and practitioners may choose to employ, for example, a microwave frequency of 2450 MHz in combination with a smaller reactor than that of the present example, without substantial departure from any other detail given herein. Single crystal CVD diamond material was grown without interruption on a surface of each of the plurality of single crystal diamond substrates to a thickness of between about 4 mm and about 6 mm. The temperature of the crystals during growth affects the amount of nitrogen incorporated for a given equivalent N₂/C₂H₂ ratio provided in the process gases. Here, temperature was measured on an area of polycrystalline diamond in between adjacent single crystals using an optical pyrometer operating at a wavelength of 2.2 μm, which was pointed through an 8 mm thick IR-grade fused silica observation window. A one-colour measurement was made assuming no transmission losses and an emissivity of 0.9 for the polycrystalline diamond, which gives a consistent and reproducible reading that is within about 10 °C of the true thermodynamic temperature, as would be measured (for example) using a two-colour pyrometer.

After growth, the CVD single crystal diamond crystals were removed from the substrate carrier and separated from the polycrystalline diamond that had grown between them. The closer spacing of the substrates allowed rotation during growth to a certain point, with a small separation between adjacent gown single crystal diamonds 11.

Further grown runs were performed under the same conditions as those described above, but with a nominal grown face size of between 7.5 and 7.7 mm using a prior art loading pattern, and a nominal grown face size of between 7.0 and 7.5 mm using a loading pattern as described herein. The resultant thickness of polycrystalline diamond later and face to face separation are shown below in Table 1.

TABLE 1

| | Nominal | Polycrystal- | Face to face |
|---|---|---|---|
| | SC face | line diamond | separation after |
| Loading pattern | size (mm) | layer (mm) | growth (mm) |
| Prior Art | 7.5-7.7 | 1.0-2.0 | 3.0-3.5 |
| Higher density | 7.0-7.5 | 0.6-0.7 | 1.4-1.9 |

It can be seen that in these examples, the face to face separation after growth was much lower for the higher loading density samples than for the prior art loading density samples, and the thickness of the polycrystalline diamond layer on each face was much lower. As described above, the reduced face to face separation constrains lateral growth and edge development during growth, and provides better lateral heat sinking between adjacent diamonds, thereby evening out fluctuations in plasma temperature across the carrier, and reducing the risk of edge-twinning.

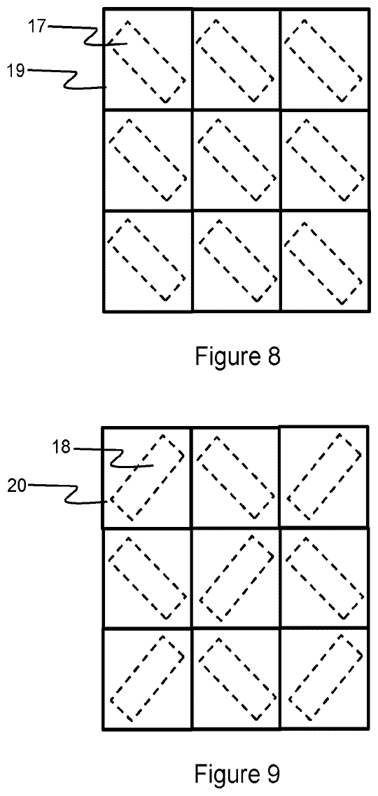

In some embodiments, at least one diamond substrate 2 is substantially rectangular in plan view, and has an aspect ratio selected from any of 1.5, 2, and 3. FIGS. 8 and 9 both illustrate schematically in plan view loading patterns with high aspect ratio single crystal diamond substrates 17, 18. The grown diamond 19, 20 will still be adjacent to at least one other grown diamond and separated by a layer of polycrystalline diamond as described above.

While this invention has been particularly shown and described with reference to embodiments, it will be understood by those skilled in the art that various changes in form and detail may be made without departing from the scope of the invention as defined by the appended claims.

1. A method of manufacturing a plurality of single crystal diamonds, the method comprising:
locating a first and a second single crystal diamond substrate on a carrier, wherein each single crystal diamond substrate comprises a growth surface lying within 15° of a {100} crystallographic plane and edges lying within 15° of a {100} crystallographic plane, wherein the first single crystal diamond substrate is separated from the second single crystal diamond substrate with a centre-to-centre separation perpendicular to a {110} plane relative to a longest edge length of the single crystal diamond substrate of at least 42 and no more than 2; and
placing the carrier and the single crystal diamond substrates into a chemical vapour deposition reactor; and
growing a first single crystal diamond and a second single crystal diamond on the first and a second single crystal diamond substrates respectively.

2. The method according to claim 1, further comprising locating more than two single crystal diamond substrates on the carrier.

3. The method according to claim 1, wherein the first single crystal diamond substrate is separated from the second single crystal diamond substrate with a centre-to-centre separation perpendicular to a {110} plane relative to a longest edge length of the single crystal diamond substrate selected from any of no more than 1.9, no more than 1.8, no more than 1.7, no more than 1.6 and no more than 1.5.

4. The method according to claim 1, wherein each single crystal diamond substrate has a largest lateral dimension selected from any of at least 2 mm, at least 3 mm, at least 4 mm, at least 5 mm, and at least 10 mm.

5. The method according to claim 1, wherein each single crystal diamond has a height above the single crystal diamond substrate growth surface selected from any of at least 0.5 mm, at least 1 mm, at least 2 mm, and at least 3 mm, at least 5 mm, at least 7 mm, and at least 10 mm.

6. The method according to claim 1, wherein a sum of an area in plan view of the diamond substrates defines a total diamond substrate area;
a sum of an area in plan view of the grown single crystal diamonds defines a total grown diamond area; and
wherein the total diamond substrate area is between 45% and 60% of the total grown diamond area.

7. The method according to claim 1, wherein the first and second diamond substrates are substantially rectangular in plan view, and have an aspect ratio between 1.5 and 3.

8. The method according to claim 1, wherein the carrier has a largest dimension in a range 30 mm to 200 mm.

9. The method according to claim 1, the method further comprising, prior to locating the first and the second single crystal diamond substrate on the carrier, coating the carrier with a layer of polycrystalline CVD diamond material; and
bonding the first and second single crystal diamond substrates to the layer of polycrystalline CVD diamond material on the carrier.

10. The method according to claim 9, wherein the layer of polycrystalline CVD diamond formed on the carrier has a thickness in a range 20 μm to 200 μm.

11. A method according to claim 9, wherein the first and second single crystal diamond substrates are bonded to the layer of polycrystalline CVD diamond material on the carrier via any of brazing and soldering.

12. A diamond product comprising:
a carrier;
a first and a second single crystal diamond substrates located on the carrier, wherein each single crystal diamond substrate comprises a growth surface lying within 15° of a {100} crystallographic plane, and edges lying within 15° of a {100} crystallographic plane; and
wherein the first single crystal diamond substrate is separated from the second single crystal diamond substrate with a centre-to-centre separation perpendicular to a {110} plane relative to a longest edge length of the single crystal diamond substrate of at least 2 and no more than 2.

13. The diamond product according to claim 12, further comprising more than two single crystal diamond substrates on the carrier.

14. The diamond product according to claim 12, wherein the first single crystal diamond substrate is separated from the second single crystal diamond substrate with a centre-to-centre separation perpendicular to a {110} plane relative to a longest edge length of the single crystal diamond substrate selected from any of no more than 1.9, no more than 1.8, no more than 1.7, no more than 1.6 and no more than 1.5.

15. The diamond product according to claim 12, wherein each single crystal diamond substrate has a largest lateral dimension selected from any of at least 2 mm, at least 3 mm, at least 4 mm, at least 5 mm, and at least 10 mm.

16. The diamond product according to claim 12, wherein the first and second diamond substrates are substantially rectangular in plan view, and have an aspect ratio between 1.5 and 3.

17. The diamond product according to claim 12, wherein the carrier has a largest dimension in a range 30 mm to 200 mm.

18. The diamond product according to claim 12, the carrier is coated with a layer of polycrystalline CVD diamond material; and
the first and second single crystal diamond substrates are bonded to the layer of polycrystalline CVD diamond material on the carrier.

19. The diamond product according to claim 18, wherein the layer of polycrystalline CVD diamond formed on the carrier has a thickness in a range 20 μm to 200 μm.

20. A diamond product according to claim 18, wherein the first and second single crystal diamond substrates are bonded to the layer of polycrystalline CVD diamond material on the carrier via any of brazing and soldering.

21. (canceled)
